(19) United States
(12) Patent Application Publication
(10) Pub. No.: US 2010/0208519 A1
(43) Pub. Date: Aug. 19, 2010

(54) SEMICONDUCTOR MEMORY DEVICE AND METHOD OF READING THE SAME

(75) Inventors: Hitoshi SHIGA, Yokohama-shi (JP); Osamu Nagao, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/706,306

(22) Filed: Feb. 16, 2010

(30) Foreign Application Priority Data
Feb. 19, 2009 (JP) 2009-036479

(51) Int. Cl. G11C 16/04

(52) U.S. Cl. 365/185.03; 365/185.18

(57) ABSTRACT

First and second data retaining circuits retain data read from memory cell and threshold voltage information indicating where in one of plural threshold voltage distributions threshold voltage of memory cell is located. Calculation device executes calculations among data retained in first and second data retaining circuit and data read by sense amplifier.

Control circuit executes first operation of reading data from adjoining memory cell connected to second word line adjoining first word line connected to selected memory cell and retaining the data in first data retaining circuit, and second operation of changing respective word line voltages applied to first word line for reading data or threshold voltage information among plural values and selecting one of plural data read out by the plural values based on data retained in first data retaining circuit. Third operation of externally outputting selected data is executed simultaneously with one of successive first and second operations.

### CROSS REFERENCE TO RELATED APPLICATIONS

This application is based on and claims the benefit of priority from prior Japanese Patent Application No. 2009-36479, filed on Feb. 19, 2009, the entire contents of which are incorporated herein by reference.

### BACKGROUND OF THE INVENTION

1. Field of the Invention

The present invention relates to a semiconductor memory device and a method of reading the same, and particularly to a nonvolatile semiconductor memory device that can store a plurality of bits in one memory cell.

2. Description of the Related Art

A NAND-type flash memory has been known as one of nonvolatile semiconductor memory devices. The NAND-type flash memory includes a memory cell array that is constituted by a plurality of NAND cell units. Each NAND cell unit includes a plurality of memory cells in series connection, and two selector transistors connected to both ends of the cell unit.

A memory cell in an erased state retains data “1”, for which the threshold voltage takes a negative value. In a data writing operation to the memory cell, electrons are injected into the floating gate of the memory cell, and the retained data is rewritten to data “0”, for which the threshold voltage takes a positive value. In a data writing operation, the NAND-type flash memory can allow only a shift of the threshold voltage from a lower value to a higher value. An inverse shift of the threshold voltage (i.e., from a higher value to a lower value) is available only by an erasing operation to a whole block.

Recently, with a view to increasing memory capacity, so-called multivalued NAND-type flash memories that store information of 2 bits or more in one memory cell have been under development. For example, in a case where one memory cell stores 3 bits, one memory cell has 2³=8 patterns of threshold voltage distributions. In this case, where one memory cell stores eight-value information, the intervals between the eight patterns of threshold voltage distributions become narrow, which might cause data to be erroneously read out in a data reading operation, leading to degradation of data reliability.

To deal with this, there is proposed a semiconductor memory device that improves data reliability by reading out not only the data to be read out but also threshold voltage information of the memory cell and affixing this information to the read-out data in order to perform error check and correction (ECC) so that any data that has been read out erroneously can be corrected (see, e.g., Japanese Patent Application Publication No. 2008-16092). Here, the threshold voltage information is information that indicates where in the threshold voltage distribution assigned with certain data the threshold voltage of the memory cell is located. However, in the case where reading of the threshold voltage information is additionally executed separately from the normal data reading operation, the total operation time required for the data reading and the reading of the threshold voltage information might be long.

Furthermore, due to minutely patterned memory cells, the threshold voltage of a given memory cell might fluctuate as influenced by an adjoining memory cell. A reading method that takes such fluctuation into account is proposed by, for example, Japanese Patent Application Publication No. 2004-326866. However, if such a reading method is applied as it is to a semiconductor memory device that reads out threshold voltage information, the operation time might be even longer.

### SUMMARY OF THE INVENTION

A semiconductor memory device according to one aspect of the present invention includes: a memory cell array including a plurality of memory cells arranged therein, the memory cells being capable of storing plural-bit information associated with a plurality of threshold voltage distributions; a sense amplifier circuit configured to read out data retained in the memory cells, and threshold voltage information indicating where in one of the plurality of threshold voltage distributions a threshold voltage of the memory cell is located; a first data retaining circuit configured to retain the data and the threshold voltage information that are readout from the memory cell; a second data retaining circuit configured to retain the data and the threshold voltage information read out from the memory cell, and externally output them; a calculation device configured to perform a calculation among the data retained by the first data retaining circuit, the data retained by the second data retaining circuit, and data read out by the sense amplifier circuit; and a control circuit configured to control a reading operation, a writing operation, and an erasing operation toward the memory cell array, the control circuit being configured to execute: a first operation of reading out data from an adjoining memory cell connected to a second word line adjacent to a first word line connected to a selected memory cell as a target of data reading, and retaining the read-out data in the first data retaining circuit; a second operation of changing each of plural kinds of word line voltages among a plurality of values, the word line voltages being applied to the first word line for reading out the data or the threshold voltage information, and selecting one of plural sets of data read out by the plurality of values of each of the word line voltages in accordance with the data retained in the first data retaining circuit; and a third operation of externally outputting the data selected in the second operation, and the third operation being executed simultaneously with one of the first operation and the second operation to be executed successively.

A method of reading a semiconductor memory device according to one aspect of the present invention is a method of reading a semiconductor memory device that includes: a memory cell array including a plurality of memory cells arranged therein, the memory cells being capable of storing plural-bit information associated with a plurality of threshold voltage distributions; and a sense amplifier circuit configured to read out data retained in the memory cell and threshold voltage information indicating where in one of the plurality of threshold voltage distributions a threshold voltage of the memory cell is located, the method including: a first operation of reading out data from an adjoining memory cell connected to a second word line adjacent to a first word line connected to a selected memory cell as a target of data reading, and retaining the read-out data as first data; a second operation of changing each of plural kinds of word line voltages among a plurality of values, the word line voltages being applied to the first word line for reading out the data or the threshold voltage information, and selecting, as second data, one of plural sets of data read out at the plurality of values of each of the word line voltages in accordance with the first data; and a third operation of executing external outputting of the second data simultaneously with one of reading of the first data and reading of the second data to be executed successively.

### BRIEF DESCRIPTION OF THE DRAWINGS

FIG. 1 is a block diagram showing the whole configuration of a memory card 20, which is a nonvolatile semiconductor memory device of a first embodiment.

FIG. 2 is a functional block diagram of the memory card 20 of FIG. 1, wherein the logic controls of a memory chip 21 and a controller 22 are combined.

FIG. 3 is a circuit diagram showing a specific configuration of a memory cell array 1.

FIG. 4 is a cross sectional diagram showing a configuration of a memory cell MC.

FIG. 5 is a cross sectional diagram showing a configuration of selector transistors S1 and S2.

FIG. 6 is a cross sectional diagram showing a configuration of a NAND cell unit NU.

FIG. 7 is a state diagram of threshold voltage distributions (a relationship diagram of threshold voltage vs. number of memory cells) in a case of storing 2-bit information in one memory cell.

FIG. 8 shows a soft bit read operation for reading out threshold voltage information.

FIG. 9 shows a configuration of a sense amplifier 3a and a data register 3b included in a sense amplifier circuit 3.

FIG. 10 is a conceptual diagram for explaining an influence given on the threshold voltage distribution of a memory cell by an adjoining memory cell.

FIG. 11 explains an outline of a corrective reading scheme.

FIG. 12 explains an outline of a corrective reading scheme.

FIG. 13 explains a data reading operation in a semiconductor memory device of a first embodiment of the present invention.

FIG. 14 explains a data reading operation in a semiconductor memory device of a second embodiment of the present invention.

FIG. 15 explains a data reading operation in a semiconductor memory device of a third embodiment of the present invention.

FIG. 16 explains a data reading operation in a semiconductor memory device of a fourth embodiment of the present invention.

FIG. 17 and FIG. 18 explain a data reading operation in a semiconductor memory device of a fifth embodiment of the present invention.

### DETAILED DESCRIPTION OF THE EMBODIMENTS

Next, the embodiments of the present invention will be explained in detail with reference to the drawings.

### First Embodiment

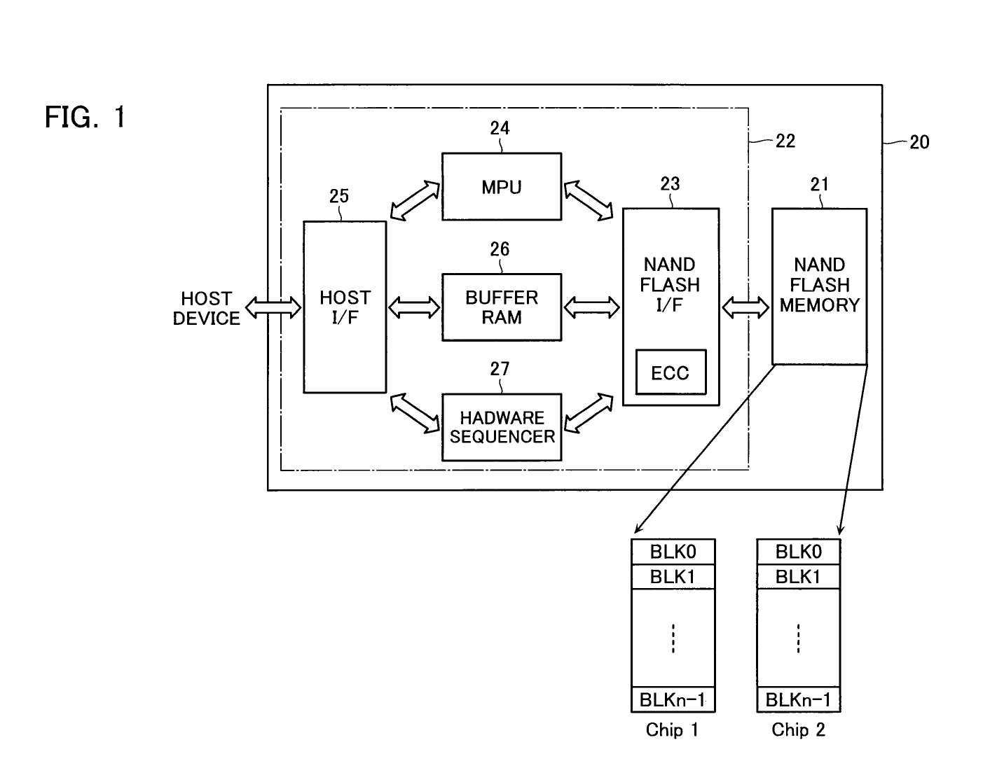

First, a semiconductor memory device of the first embodiment of the present invention will be explained with reference to FIG. 1, etc.

### [Whole Configuration of the System]

FIG. 1 is a block diagram showing the overall configuration of a memory card 20, which is the nonvolatile semiconductor memory device of the first embodiment. The memory card 20 constitutes a module by including a NAND-type flash memory chip 21 and a memory controller 22 that controls reading/writing of the flash memory chip 21. In some case, a plurality of NAND-type flash memory chips 21 may be included. FIG. 1 shows two memory chips chip1 and chip2. In this case too, the only one memory controller 22 performs memory control. The memory controller 22 is a one-chip controller that includes: a NAND flash interface 23 that intermediates in data transfer to/from the memory chip 21; a MPU 24 that executes data transfer control and operation control for the whole memory card; a host interface 25 that intermediates in data transfer to/from a host device; a buffer RAM 26 that temporarily retains data read out or to be written; and a hardware sequencer 27 used for sequence control for reading/writing of firmware (FW) in the NAND-type flash memory 21.

When the power of the memory card 20 is turned on, an initialization operation (a power-on/initial setup operation) for automatically reading the firmware (control program) stored in the flash memory 21 is executed, to transfer the firmware to a data register (buffer RAM) 26. This reading control is executed by the hardware sequencer 27.

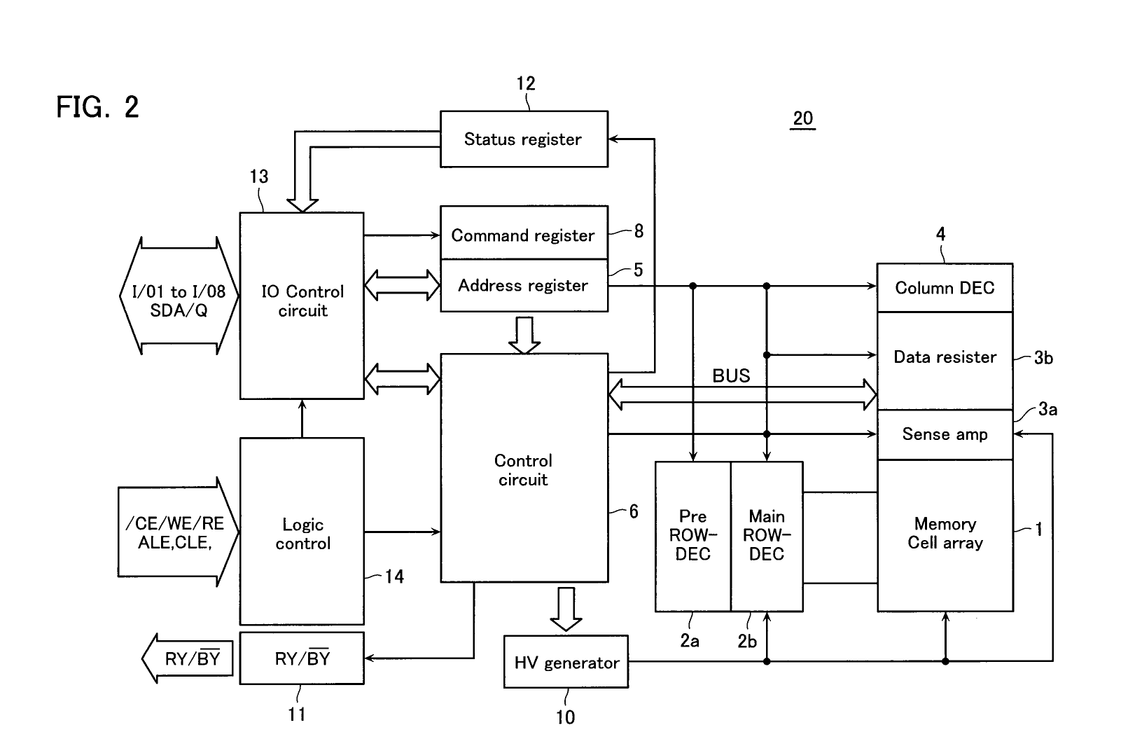

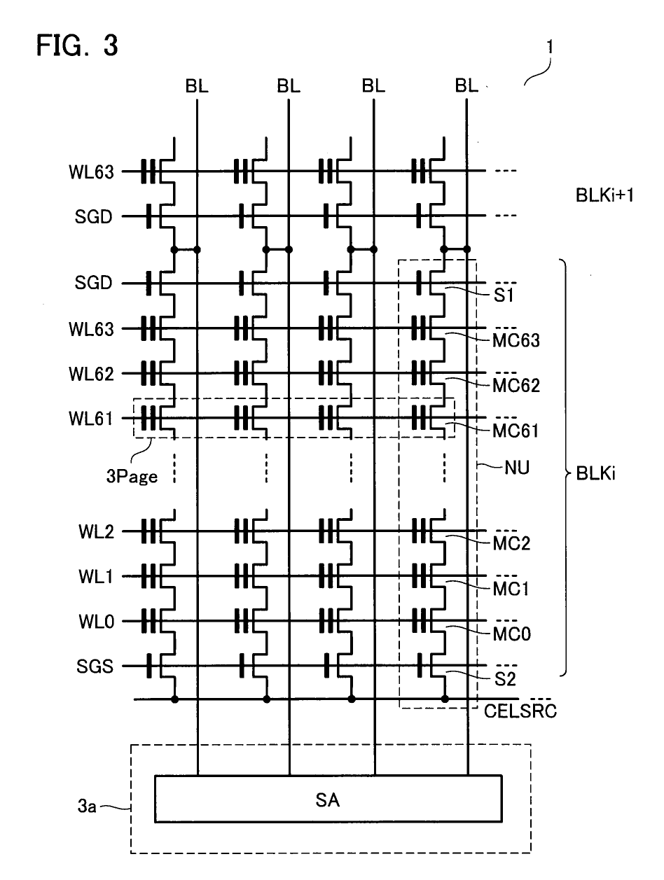

The firmware loaded onto the buffer RAM 26 causes the MPU 24 to generate various tables in the buffer RAM 26, or to access the flash memory 21 and execute data transfer control in response to a command from a host device. The NAND flash interface 23 includes an ECC circuit that executes error correction for read-out data based on redundant data stored in the flash memory chip 21. Note that it is nonessential for this memory system that the flash memory chip 21 and the controller chip 21 are separate chips. FIG. 2 shows a functional block configuration of the memory card 20 of FIG. 1, wherein the logic controls of the memory chip 21 and the controller 22 are combined. FIG. 3 shows the cell array configuration of the memory core portion of the memory card 20.

### [Configuration of Memory Cell Array 1]

As shown in FIG. 3, a memory cell array 1 is constituted by arraying NAND cell units (NAND strings) NU, in each of which a plurality of electrically rewritable nonvolatile memory cells (64 memory cells in the figure) MC0-MC63 are connected in series. The plurality of NAND cell units NU share word lines WL in common and form one block BLK.

One block BLK constitutes one unit by which a data erasing operation is executed. In a case where 2-bit data is stored in one memory cell MC (2 bits/cell), data amounting to 2 pages (upper-order page UPPER and lower-order page LOWER) is stored in the memory cells MC that are formed along one word line WL. In one memory cell array 1, the number of word lines WL in one block BLK is 64, and the number of pages in one block is 64×2=128 pages.

As shown in FIG. 3, one end of a NAND cell unit NU is connected via a selector gate transistor S1 to a bit line BL, and the other end thereof is connected via a selector gate transistor S2 to a common source line CELSRC. The gates of the selector gate transistors S1 and S2 are connected to selector gate lines SGD and SGS. Control gates of the memory cells MC0 to MC63 are connected to the word lines WL0 to WL63 respectively.

A sense amplifier 3a used for reading/writing of cell data is disposed at one end side of the bit lines BL, and a row decoder 2 (not shown in FIG. 3) that selects and drives the word lines and selector gate lines is disposed at one end side of the word lines WL.

As shown in FIG. 2, a command, an address, and data are input via an input/output control circuit 13, and a chip enable signal CE, a write enable signal WE, a read enable signal RE, and other external control signals are input to a logic control circuit and used for timing control. The command is decoded by a command register 8.

A control circuit 6 executes data transfer control and data sequence control for writing, erasing, and reading. A status register 11 outputs a ready/busy status of the memory card 20 to a ready/busy terminal. Separately from this register, a status register 12 that notifies the statuses (pass/fail, ready/busy, etc.) of the memory 20 to the host via an I/O port is provided.

An address is transferred via an address register 5 to the row decoder (a pre-row decoder 2a and a main row decoder 2b) 2 and to a column decoder 4. Data to be written is loaded via the input/output control circuit 13, the control circuit 6, and a data bus BUS onto a sense amplifier circuit 3 (the sense amplifier 3a and a data register 3b), and read-out data is externally output via the control circuit 6.

A high voltage generator circuit 10 is provided for generating a high voltage required in each operation mode. The high voltage generator circuit 10 generates a predetermined high voltage based on an instruction issued by the control circuit 6.

### [Configuration of Memory Cell MC and Selector Gates S1 and S2]

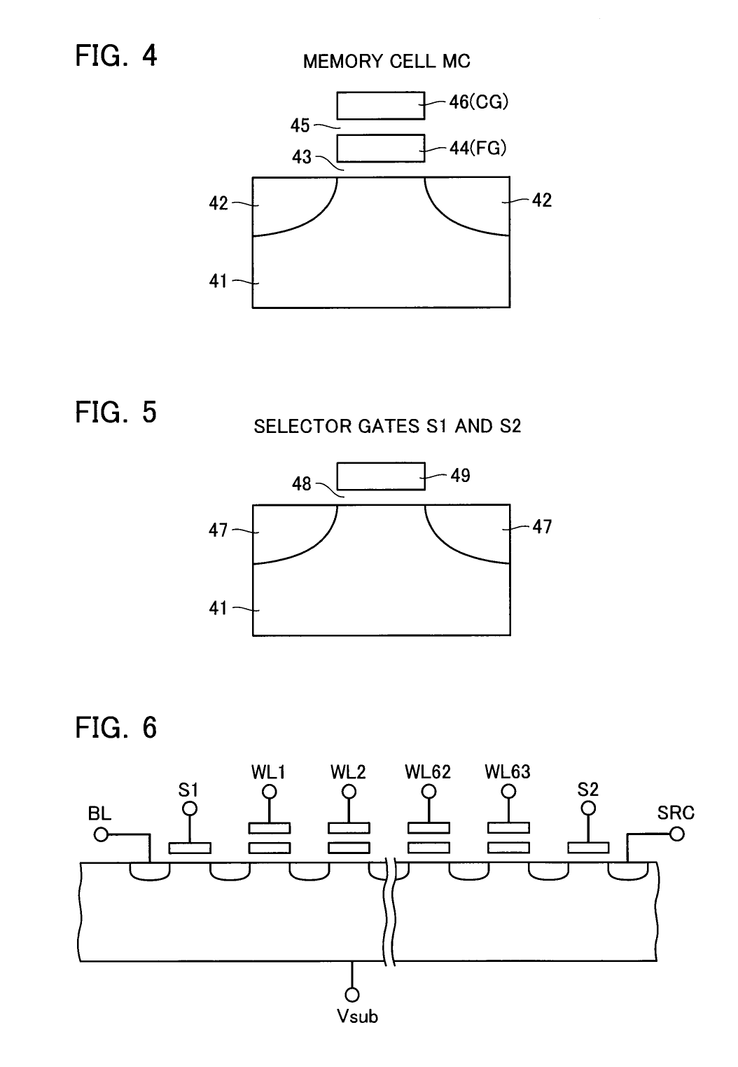

FIG. 4 and FIG. 5 show cross-sectional structures of a memory cell MC and selector gates S1 and S2. An n-type diffused layer 42, which functions as a source and drain of a MOSFET that constitutes a memory cell MC, is formed on a substrate 41. A floating gate (FG) 44 is formed above the substrate 41 via a gate insulating film 43, and a control gate (CG) 46 is formed above the floating gate 44 via an insulating film 45.

The selector gates S1 and S2 comprise the substrate 41, and an n-type diffused layer 47 as their source and drain formed on the substrate 41. A control gate 49 is formed above the substrate 41 via a gate insulating film 48.

### [NAND Cell Unit NU]

FIG. 6 shows a cross section of one NAND cell unit NU in the memory cell array 1. In this example, one NAND cell unit NU is formed of series-connected 64 memory cells MC each having the configuration of FIG. 4. The first selector gate S1 and second selector gate S2 each having the configuration of FIG. 5 are provided at the drain and source sides of the NAND cell unit NU respectively.

### [Multivalue Storage of NAND-Type Flash Memory]

Next, multivalue storage of the NAND-type flash memory having the above-described configuration will be explained. The NAND-type flash memory can store 2-bit data in one memory cell by controlling the value of the threshold voltage of one memory cell in four ways. A case of four-value storage will hereinafter be explained as an example, but needless to say, the present invention can also be applied to other cases including eight-value (3-bit) or higher multivalue storage.

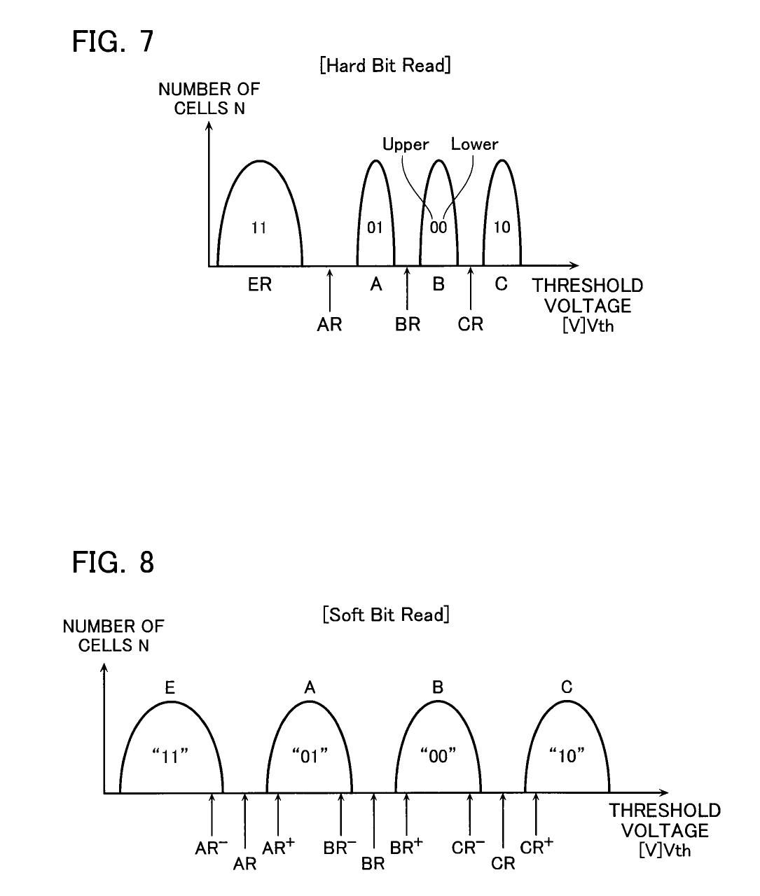

FIG. 7 shows a state diagram of threshold voltage distributions (a relationship diagram of threshold voltage vs. number of memory cells) in the case of storing 2-bit information in one memory cell. For 2-bit information to be stored, writing/reading of information is executed while four kinds of threshold voltage distributions (ER, and A to C) are set for four patterns of data “11”, “01”, “00”, and “10” correspondingly. That is, any of the four patterns of bit information (11, 01, 00, and 01) is associated with any of the four patterns of threshold voltage distributions (ER, and A to C) respectively. Two sub-pages are formed for this 2-bit data. The two sub-pages are namely an upper-order page UPPER and a lower-order page LOWER.

### [Normal Data Reading (Hard Bit Read)]

In a reading operation, the four patterns of data are read out by applying a reading voltage to the selected word line WL connected to the memory cell MC to detect whether the memory cell MC is in or out of electrical conduction. Corresponding to the four patterns of threshold voltage distributions of the memory cell, the voltage value of the reading voltage to be applied to the selected word line WL can be set to voltages AR, BR, and CR (three patterns), each of which is of a value between the upper limit and lower limit of the threshold voltage distributions as shown in FIG. 7. The reading voltage AR is the lowest voltage, and the voltage values increase from BR to CR. The voltage to be applied to non-selected memory cells MC in the reading operation is set to a voltage higher than the threshold voltage distribution C with which the data “10” is associated.

### [Threshold Voltage Information Reading (Soft Bit Read)]

When multivalue (e.g., four-value) information is stored in one memory cell MC, the intervals between the four patterns of threshold voltage distributions become narrow. As a result, data might be erroneously read out in the data reading operation, and data reliability might drop. Hence, it is necessary to perform error check and correction (ECC) for correcting the data erroneously readout. In performing error check and correction, it is possible to make the error check and correction highly accurate, by reading out not only the data to be read out but also threshold voltage information of the memory cell MC and affixing this information to the read-out data. Here, threshold voltage information is information that indicates where in one of the threshold voltage distributions (ER, A, B, and C) the threshold voltage value of the memory cell MC is located (for example, whether the threshold voltage value is about the center, at the right-hand side, or at the left-hand side in the threshold voltage distribution A). In other words, the threshold voltage information is information indicating the “correctness” of the read-out data. Reading of this threshold voltage information will hereinafter be referred to as “soft bit read”. In contrast with this, reading of normal data (“11”, “01”, “00”, and “10”) will be referred to as “hard bit read”.

To execute soft bit read for reading this threshold voltage information, in the present embodiment, voltages AR−, AR+, BR−, BR+, CR−, and CR+ as shown in FIG. 8 in addition to the aforementioned voltages AR, BR, and CR are applied to a selected word line WL, and reading is executed at each voltage. The data read out here is the aforementioned threshold voltage information. The voltage AR− is a voltage lower than the voltage AR by a predetermined value. The voltage AR+ is a voltage higher than the voltage AR by a predetermined value. The voltage BR− is a voltage lower than the voltage BR by a predetermined value. The voltage BR+ is a voltage higher than the voltage BR by a predetermined value. The voltage CR− is a voltage lower than the voltage CR by a predetermined value. The voltage CR+ is a voltage higher than the voltage CR by a predetermined value. These predetermined values may be the same or different among the voltages AR−, AR+, BR−, BR+, CR−, and CR+.

### [Configuration of Sense Amplifier Circuit 3]

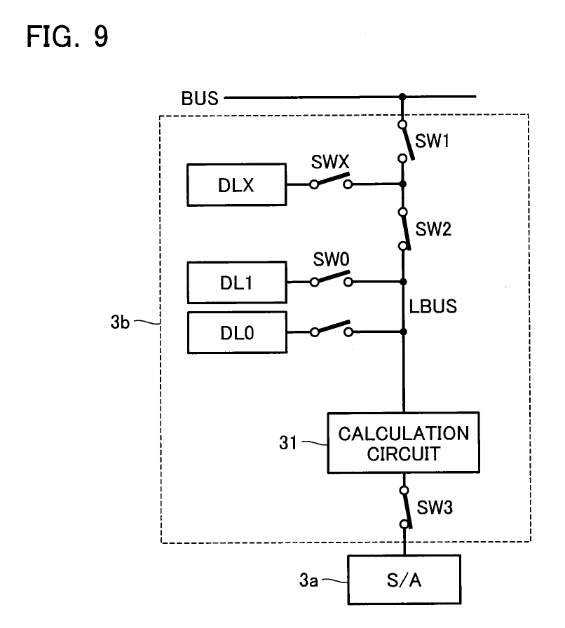

Next, the configuration of the sense amplifier circuit suitable for reading normal data (hard bit read), and threshold voltage information (soft bit read) from a memory cell MC that retains data on a 2 bits per cell basis will be explained. FIG. 9 shows the configuration of the sense amplifier 3a and the data register 3b included in the sense amplifier circuit 3.

The data register 3b includes a calculation circuit 31 that executes logic calculations on data read out by the sense amplifier 3a, and three data latches DL0, DL1, and DLX that temporarily retain data output by the calculation circuit 31. The data latches DL0 and DL1 are connected via respective switches SW0 to a local bus LBUS of the data register 3b such that data is input thereto or output therefrom.

The data register 3b includes a switch SW1 that connects the data register 3b and the data bus BUS, a switch SW2 that connects the local bus LBUS and the data latch DLX, and a switch SW3 that connects the sense amplifier 3a and the calculation circuit 31. The switch SW1 and switch SW2 are complimentarily controlled such that one is closed when the other is opened. A switch SWX is closed synchronously with either the switch SW1 or the switch SW2, thereby connecting the data latch DLX to either the local bus LBUS or the data bus BUS.

The calculation circuit 31 has a function of executing logic calculations between data detected (read out) by the sense amplifier 3a and data retained by the data latch DL and logic calculations between data retained by a plurality of data latches DL, and transferring the calculation result to the data latch DL. The data latch DLX can externally exchange data through the data bus BUS, by switching off the switch SW2 and switching on the switch SW1.

The data register 3b of the present embodiment retains read-out data in the data latch DLX, and can externally output the data retained in the data latch DLX by switching off the switch SW2 and switching on the switch SW1. At the same time as this, the data register 3b can execute a reading operation described later by using the sense amplifier 3a and the data latches DL0 to DL1.

[Corrective Reading Scheme taking into Account Influence of Interference Between Adjoining Memory Cells]

The present embodiment employs a reading scheme (corrective reading scheme) that takes into account the influence of interference between adjoining memory cells. The corrective reading scheme will now be explained.

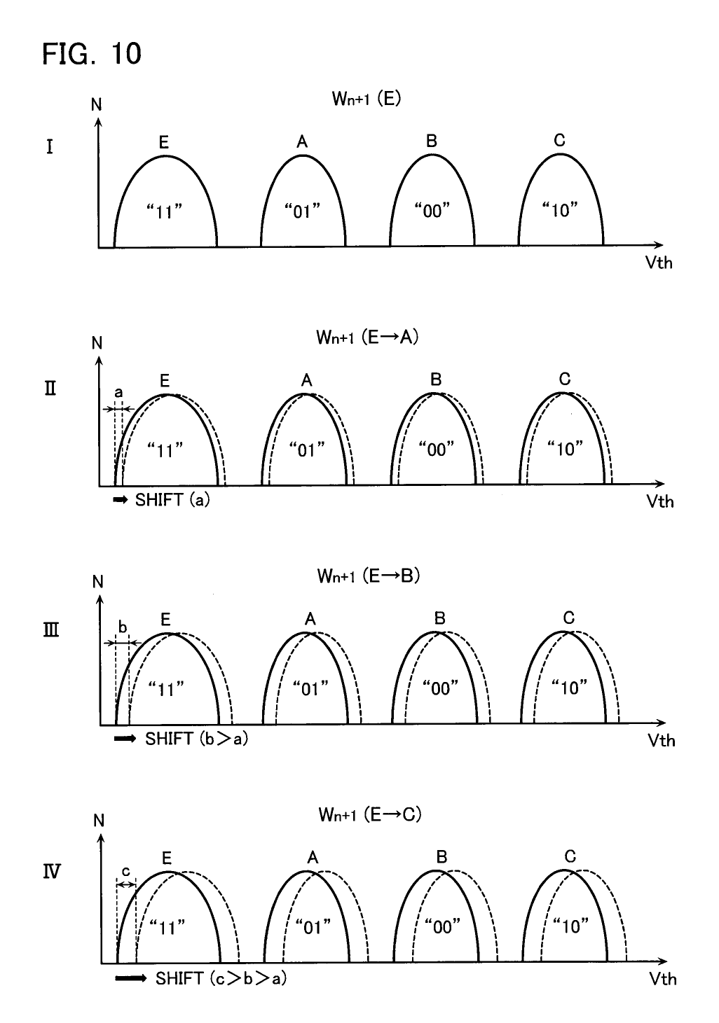

FIG. 10 is a conceptual diagram for explaining the influence of interference between adjoining memory cells. As the NAND-type flash memory is more and more minutely patterned and memory cells become more integrated, the distance between memory cells becomes shorter to cause a heavier interference between adjoining cells. Therefore, the threshold voltage distribution of a given memory cell is influenced by a writing operation to another memory cell adjacent thereto. For example, the threshold distribution of a memory cell along a word line WLn is influenced by an adjoining memory cell that is connected to the word line WLn+1 that adjoins the word line WLn. The degree of the influence varies according to which of “11”, “01”, “00”, and “10” the data written in the adjoining memory cell is. That is, as the adjoining memory cell has a higher threshold voltage, the influence thereof becomes greater (see FIG. 10).

As shown at the symbol I of FIG. 10, as long as the threshold voltage distribution of the adjoining memory cell remains E (“11”), the memory cell along the word line WLn is not influenced by the adjoining memory cell. However, when writing is executed to the adjoining memory cell such that its threshold voltage distribution changes from E to A (“01”), B (“00”), or C (“10”), the threshold voltage distribution of the memory cell along the word line WLn also changes (or a shift of the threshold voltage distribution becomes larger) as influenced by that change. When the adjoining memory cell is written such that its threshold voltage distribution becomes C (“10”), the shift amount of the threshold voltage distribution of the memory cell MC along the word line WLn is greater than when the adjoining memory cell is written to be in any other distribution.

As such, since the threshold voltage distribution of a given memory cell changes under the influence of an adjoining memory cell and the degree of this influence varies according to the value of the multivalue data written in the adjoining memory cell, the margins between the threshold voltage distributions (E, A, B, and C) of the memory cells become smaller, making it harder to appropriately set the level of the reading voltage. Hence, the corrective reading scheme reads out data from a given target memory cell, by reading data from its adjoining memory cell (a memory cell to be written subsequently) while changing the level of the voltage to be applied to the word line WLn corresponding to that reading target memory cell in accordance with the data of the adjoining memory cell. This can reduce the influence of the adjoining memory cell and the possibility of erroneous reading, etc.

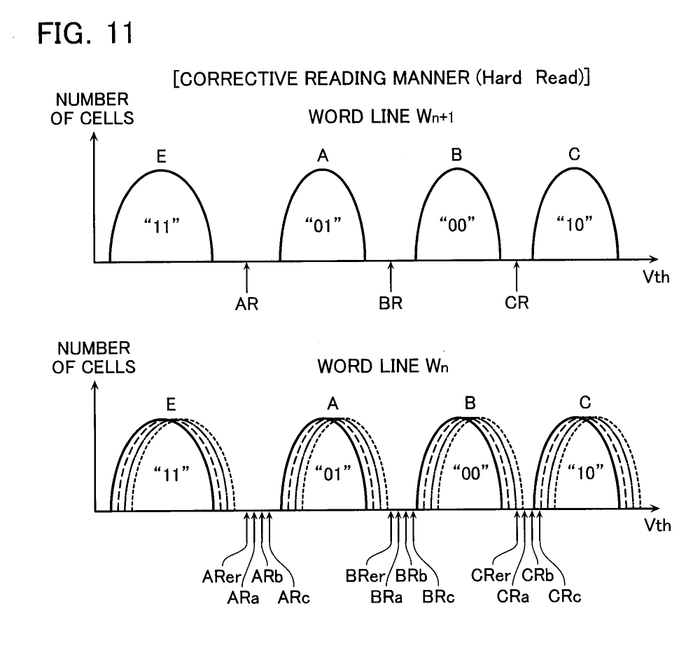

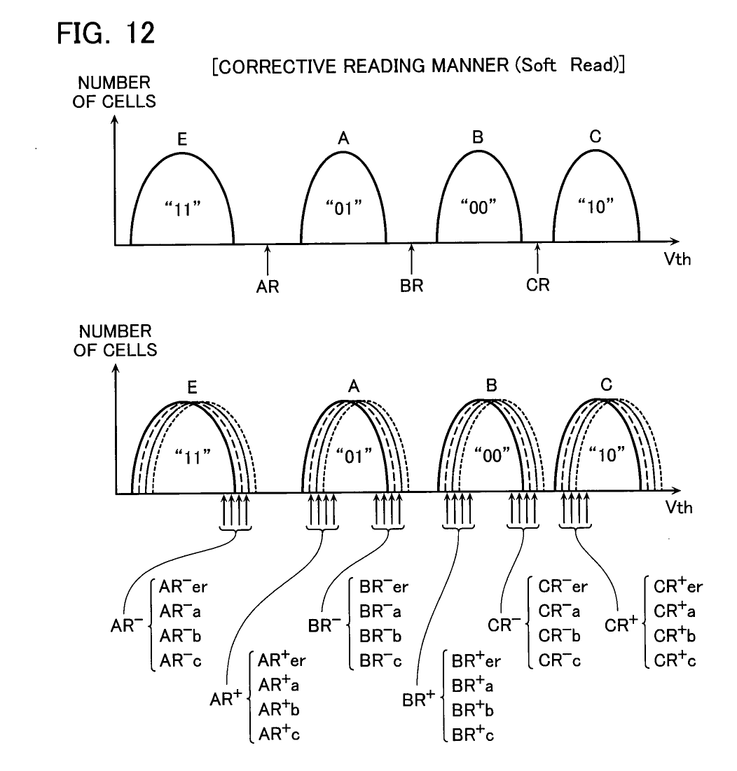

Next, the outline of the corrective reading scheme will be explained with reference to FIG. 11 and FIG. 12. In executing hard bit read, the corrective reading scheme minutely changes the voltage AR to be applied to the word line WLn among four levels (voltages ARer, ARa, ARb, and ARc). The voltage ARer is the lowest voltage that is effective (or selected) when the data retained in the adjoining memory cell along the word line WLn+1 is data “11” (threshold voltage distribution E=erased state). The voltage ARa is effective (or selected) when the data retained in the adjoining memory cell is data “01” (threshold voltage distribution A), and is a voltage higher than the voltage ARer. The voltage ARb is effective (or selected) when the data retained in the adjoining memory cell is data “00” (threshold voltage distribution B), and is a voltage higher than the voltage ARa. The voltage ARc is effective (or selected) when the data retained in the adjoining memory cell is data “10” (threshold voltage distribution C), and is a voltage higher than the voltage ARb.

Likewise, the voltage BR to be applied to the word line WLn for data reading is minutely changed among four levels (voltages BRer, BRa, BRb, and BRc). The voltage BRer is the lowest voltage that is effective (or selected) when the data retained in the adjoining memory cell is data “11” (threshold voltage distribution E=erased state). The voltage BRa is effective (or selected) when the data retained in the adjoining memory cell is data “01” (threshold voltage distribution A), and is a voltage higher than the voltage BRer. The voltage BRb is effective (or selected) when the data retained in the adjoining memory cell is data “00” (threshold voltage distribution B), and is a voltage higher than the voltage BRa. The voltage BRc is effective (or selected) when the data retained in the adjoining memory cell is data “10” (threshold voltage distribution C), and is a voltage higher than the voltage BRb.

Likewise, the voltage CR to be applied to the word line WLn for data reading is minutely changed among four levels (voltages CRer, CRa, CRb, and CRc). The voltage CRer is the lowest voltage that is effective (or selected) when the data retained in the adjoining memory cell is data “11” (threshold voltage distribution E=erased state). The voltage CRa is effective (or selected) when the data retained in the adjoining memory cell is data “01” (threshold voltage distribution A), and is a voltage higher than the voltage CRer. The voltage CRb is effective (or selected) when the data retained in the adjoining memory cell is data “00” (threshold voltage distribution B), and is a voltage higher than the voltage CRa. The voltage CRc is effective (or selected) when the data retained in the adjoining memory cell is data “10” (threshold voltage distribution C), and is a voltage higher than the voltage CRb.

In this way, in the present embodiment, the voltages AR, BR, and CR to be applied for hard bit read are each changed among four levels of voltages. Then, from among four sets of data obtained for the four levels of voltages respectively, data that corresponds to the data retained in the adjoining memory cell is selected and used for specifying the data to be read out from the selected memory cell MCn. For example, when the data retained in the adjoining memory cell is “00” (threshold voltage distribution B), the data obtained at the voltages ARb, BRb, and CRb are specified as the data to be read out from the selected memory cell.

Each of the voltages AR−, AR+, BR−, BR+, CR−, and CR+ to be applied for soft bit read can also be changed among four levels of voltages in accordance with the data retained in the adjoining memory cell. That is, the corrective reading scheme is also executed for soft bit read. In accordance with the data retained in the adjoining memory cell, data that is read out at one of these four levels of voltages is selected and output as the data read out from the selected memory cell.

For example, the voltage AR− is changed among four levels of voltages AR−er, AR−a, AR−b, and AR−c in accordance with the state of the adjoining memory cell. The voltage AR−er is the lowest voltage that is effective (or selected) when the data retained in the adjoining memory cell is data “11” (threshold voltage distribution E=erased state). The voltage AR−a is effective (or selected) when the data retained in the adjoining memory cell is data “01” (threshold voltage distribution A), and is a voltage higher than the voltage AR−er. The voltage AR−b is effective (or selected) when the data retained in the adjoining memory cell is data “00” (threshold voltage distribution B), and is a voltage higher than the voltage AR−a. The voltage AR−c is effective (or selected) when the data retained in the adjoining memory cell is data “10” (threshold voltage distribution C), and is a voltage higher than the voltage AR−b.

The voltage AR+ is changed among four levels of voltages AR+er, AR+a, AR+b, and AR+c. The voltage AR+er is effective (or selected) when the data retained in the adjoining memory cell is data “11” (threshold voltage distribution E=erased state), and is the lowest voltage. The voltage AR+a is effective (or selected) when the data retained in the adjoining memory cell is data “01” (threshold voltage distribution A), and is a voltage higher than the voltage AR+er. The voltage AR+b is effective (or selected) when the data retained in the adjoining memory cell is data “00” (threshold voltage distribution B), and is a voltage higher than the voltage AR+a. The voltage AR+c is effective (or selected) when the data retained in the adjoining memory cell is data “10” (threshold voltage distribution C), and is a voltage higher than the voltage AR+b.

The voltage BR− is changed among four levels of voltages BR−er, BR−a, BR−b, and BR−c. The voltage BR−er is effective (or selected) when the data retained in the adjoining memory cell is data “11” (threshold voltage distribution E=erased state), and is the lowest voltage. The voltage BR−a is effective (or selected) when the data retained in the adjoining memory cell is data “01” (threshold voltage distribution A), and is a voltage higher than the voltage BR−er. The voltage BR−b is effective (or selected) when the data retained in the adjoining memory cell is data “00” (threshold voltage distribution B), and is a voltage higher than the voltage BR−a. The voltage BR−c is effective (or selected) when the data retained in the adjoining memory cell is data “10” (threshold voltage distribution C), and is a voltage higher than the voltage BR−b.

The voltage BR+ is changed among four levels of voltages BR+er, BR+a, BR+b, and BR+c. The voltage BR+er is the lowest voltage that is effective (or selected) when the data retained in the adjoining memory cell is data “11” (threshold voltage distribution E=erased state). The voltage BR+a is effective (or selected) when the data retained in the adjoining memory cell is data “01” (threshold voltage distribution A), and is a voltage higher than the voltage BR+er. The voltage BR+b is effective (or selected) when the data retained in the adjoining memory cell is data “00” (threshold voltage distribution B), and is a voltage higher than the voltage BR+a. The voltage BR+c is effective (or selected) when the data retained in the adjoining memory cell is data “10” (threshold voltage distribution C), and is a voltage higher than the voltage BR+b.

The voltage CR− is changed among four levels of voltages CR−er, CR−a, CR−b, and CR−c. The voltage CR−er is the lowest voltage that is effective (or selected) when the data retained in the adjoining memory cell is data “11” (threshold voltage distribution E=erased state). The voltage CR−a is effective (or selected) when the data retained in the adjoining memory cell is data “01” (threshold voltage distribution A), and is a voltage higher than the voltage CR−er. The voltage CR−b is effective (or selected) when the data retained in the adjoining memory cell is data “00” (threshold voltage distribution B), and is a voltage higher than the voltage CR−a. The voltage CR−c is effective (or selected) when the data retained in the adjoining memory cell is data “10” (threshold voltage distribution C), and is a voltage higher than the voltage CR−b.

The voltage CR+ is changed among four levels of voltages CR+er, CR+a, CR+b, and CR+c. The voltage CR+er is effective (or selected) when the data retained in the adjoining memory cell is data “11” (threshold voltage distribution E=erased state), and is the lowest voltage. The voltage CR+a is effective (or selected) when the data retained in the adjoining memory cell is data “01” (threshold voltage distribution A), and is a voltage higher than the voltage CR+er. The voltage CR+b is effective (or selected) when the data retained in the adjoining memory cell is data “00” (threshold voltage distribution B), and is a voltage higher than the voltage CR+a. The voltage CR+c is effective (or selected) when the data retained in the adjoining memory cell is data “10” (threshold voltage distribution C), and is a voltage higher than the voltage CR+b.

As described above, the semiconductor memory device of the first embodiment executes soft bit read in addition to hard bit read, and executes the corrective reading scheme for each of them. Performing the procedures of these operations in turn might prolong the time required for data reading. Hence, the semiconductor memory device of each embodiment of the present invention to be explained hereinbelow will shorten the time required for data reading, by executing the operation of outputting the hard bit read data or soft bit read data read out in the corrective reading scheme concurrently (simultaneously) with the operation to be executed subsequently of reading/retaining data from an adjoining memory cell or with hard bit read or soft bit read to be executed subsequently to a selected memory cell.

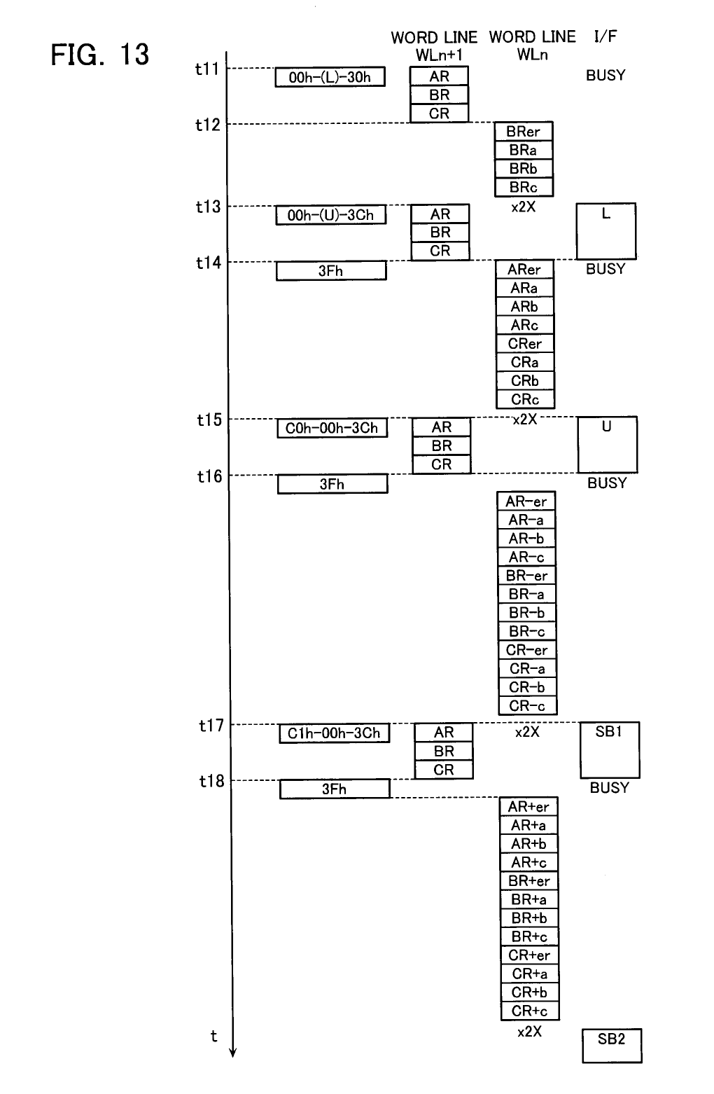

Next, with reference to FIG. 13, a data reading operation of the semiconductor memory device of the first embodiment of the present invention will be explained. FIG. 13 shows the voltages to be applied to the word line WLn to which a selected memory cell MCn is connected, the voltages to be applied to the adjoining word line WLn+1 to which is connected the adjoining memory cell MCn+1 that adjoins the selected memory cell MCn, and outputting operations via an external output interface I/F.

First, at a timing t11, a reading operation to an adjoining memory cell MCn+1 along the adjoining word line WLn+1 is executed in accordance with a read command, so the voltages AR, BR, and CR are applied sequentially to the adjoining word line WLn+1. As a result, 2-bit data corresponding to the four-value data stored in the adjoining memory cell MCn+1 is read out via the calculation circuit 31 and stored in the two data latches DL1 and DL0 of the data register 3b shown in FIG. 9.

Next, at a timing t12, hard bit read to the word line WLn is partially executed. Specifically, for reading the lower-order data (LOWER) in the selected memory cell MCn, the voltage BR is applied as switched among the four levels (BRer, BRa, BRb, and BRc), and four sets of read-out data are obtained for the four levels of voltages respectively as the data read out from the selected memory cell MCn (that is, the lower-order data (LOWER) out of the 2-bit data in the memory cell MCn is read out).

These four sets of read-out data are once stored in a data latch (unillustrated) in the calculation circuit 31. Then, the calculation circuit 31 selects one of the four sets of read-out data in accordance with the data in the adjoining memory cell MCn+1 stored in the data latches DL1 and DL0, and the selected data is transferred to and stored in the data latch DLX as the lower-order data (LOWER) of the memory cell MCn.

Specifically, when the data stored in the memory cell MCn+1 is data “11” associated with the threshold voltage distribution E (in which case, “1” and “1” are stored in the data latches DL0 and DL1 respectively), data that is read out when the voltage BRer is applied is selected and transferred to and stored in the data latch DLX.

Likewise, when the data stored in the memory cell MCn+1 is data “01” associated with the threshold voltage distribution A (in which case, “1” and “0” are stored in the data latches DL0 and DL1 respectively), data that is read out when the voltage BRa is applied is selected and transferred to and stored in the data latch DLX.

Likewise, when the data stored in the memory cell MCn+1 is data “00” associated with the threshold voltage distribution B (in which case, “0” and “0” are stored in the data latches DL0 and DL1 respectively), data that is read out when the voltage BRb is applied is selected and transferred to and stored in the data latches DLX.

Still likewise, when the data stored in the memory cell MCn+1 is data “10” associated with the threshold voltage distribution C (in which case, “0” and “1” are stored in the data latches DL0 and DL1 respectively), data that is read out when the voltage BRc is applied is selected and transferred to and stored in the data latch DLX.

Next, at a timing t13, in accordance with a new read command, the voltages AR, BR, and CR are sequentially applied to the adjoining word line WLn+1, and data is read out from an adjoining memory cell MCn+1. The read-out data is stored in the data latches DL0 and DL1.

Meanwhile, at the same time as this, the data (lower-order data (LOWER) in the selected memory cell MCn) stored in the data latch DLX at the timing t12 is externally output from the external interface I/F. In this way, reading of data from an adjoining memory cell MCn+1 along the adjoining word line WLn+1 and outputting of data read out from a memory cell MCn along the selected word line WLn are executed concurrently, leading to shortening of the time required for data reading.

Next, at a timing t14, in accordance with issuance of a new read command, the voltage AR is applied to the word line WLn with the voltage value thereof switched among the four levels (ARer, ARa, ARb, and ARc), and subsequently the voltage CR is applied thereto likewise as switched among the four levels (CRer, CRa, CRb, and CRc). The 8 (=2×4) sets of data (the upper-order data (UPPER) in a memory cell MCn) read out here are once stored in the data latch (unillustrated) in the calculation circuit 31. Then, in accordance with the data in the adjoining memory cell MCn+1 stored in the data latches DL1 and DL0, two of these eight sets of read-out data are selected by the calculation circuit 31, and only these selected data are kept in the calculation circuit 31, with the other data deleted.

That is, when the data in the memory cell MCn+1 turns out to be “11” as a result of referring to the data stored in the data latches DL0 and DL1, data that are read out at the voltages ARer and CRer are only selected, and the other data are deleted. Likewise, when the data in the memory cell MCn+1 is “01”, data that are read out at the voltages ARa and CRa are only selected, and the other data are deleted. When the data in the memory cell MCn+1 is “00”, data that are read out at the voltages ARb and CRb are only selected, and the other data are deleted. When the data in the memory cell MCn+1 is “10”, data that are read out at the voltages ARc and CRc are only selected, and the other data are deleted.

Next, at a timing t15, in accordance with issuance of a new read command, a reading operation to an adjoining memory cell MCn+1 along the adjoining word line WLn+1 is executed, and the voltages AR, BR, and CR are sequentially applied to the adjoining word line WLn+1. As a result, 2-bit data corresponding to the four-value data stored in the adjoining memory cell MCn+1 is read out via the calculation circuit 31, and stored in the two data latches DL1 and DL0 in the data register 3b shown in FIG. 9.

Meanwhile, at the same time as this, the data (the upper-order data (UPPER) in the selected memory cell MCn) stored in the data latch (unillustrated) in the calculation circuit 31 is externally output from the external interface I/F. In this way, reading of data from an adjoining memory cell MCn+1 along the adjoining word line WLn+1 and outputting of data read out from a memory cell MCn along the selected word line WLn are executed concurrently, leading to shortening of the time required for data reading.

Next, from a timing t16, a first soft bit read operation is executed. That is, at the timing t16, in accordance with issuance of a new read command, the voltages AR−, BR−, and CR− are applied to the word line WLn with the voltage value of each switched among the four levels (the four levels of AR−er, AR−a, AR−b, and AR−c; the four levels of BR−er, BR−a, BR−b, and BR−c; and the four levels of CR−er, CR−a, CR−b, and CR−c). The 12 (=3×4) sets of read-out data, which are readout here, are once stored in the data latch (unillustrated) in the calculation circuit 31. Then, in accordance with the data in the adjoining memory cell MCn+1 stored in the data latches DL1 and DL0, three of these twelve sets of read-out data are selected by the calculation circuit 31, and only these selected data are kept in the calculation circuit 31, with the other data deleted.

Next, at a timing t17, in accordance with issuance of a new read command, a reading operation to an adjoining memory cell MCn+1 along the adjoining word line WLn+1 is executed, and the voltages AR, BR, and CR are sequentially applied to the adjoining word line WLn+1. As a result, 2-bit data corresponding to four-value data stored in the adjoining memory cell MCn+1 is read out via the calculation circuit 31 and stored in the two data latches DL1 and DL0.

Meanwhile, at the same time as this, the data (the first soft bit read data from the selected memory cell MCn read out at the timing t16) stored in the data latch (unillustrated) in the calculation circuit 31 are externally output from the external interface I/F. In this way, reading of data from an adjoining memory cell MCn+1 along the adjoining word line WLn+1 and outputting of first soft bit read data read out from a memory cell MCn along the selected word line WLn are executed concurrently, leading to shortening of the time required for data reading.

Next, at a timing t18, a second soft bit read operation is successively executed. That is, in accordance with issuance of a new read command, the voltages AR+, BR+, and CR+ are applied to the word line WLn with the voltage value of each switched among the four levels (the four levels of AR+er, AR+a, AR+b, and AR+c; the four levels of BR+er, BR+a, BR+b, and BR+c; and the four levels of CR+er, CR+a, CR+b, and CR+c). The 12 (=3×4) sets of read-out data, which are read out here, are once stored in the data latch (unillustrated) in the calculation circuit 31.

After this, in accordance with the data in the adjoining memory cell MCn+1 that is stored in the data latches DL1 and DL0, three of these twelve sets of read-out data are selected by the calculation circuit 31, and only these selected data are kept in the calculation circuit 31, with the other data deleted. The second soft bit read data read out in this way are subsequently externally output from the external interface I/F. The second soft bit read data output here and the first soft bit read data output previously at the timing t17 are combined and form soft bit read data, which is to be used for error correction at the ECC circuit.

As explained above, according to the present embodiment, hard bit read and soft bit read for a memory cell MCn formed along the word line WLn are executed in the corrective reading scheme that executes reading by changing the voltages AR, BR, CR, AR−, BR−, CR−, AR+, BR+, and CR+ among four levels, and any of the data read out at these four levels is selected in accordance with the data in the adjoining memory cell MCn+1 along the adjoining word line WLn+1. This enables a reading operation to be executed without being influenced by interference from the adjoining cell. Since data reading in this scheme allows reading from a memory cell MCn+1 and outputting of data in a memory cell MCn to be executed concurrently, the time required for reading can be shortened.

### Second Embodiment

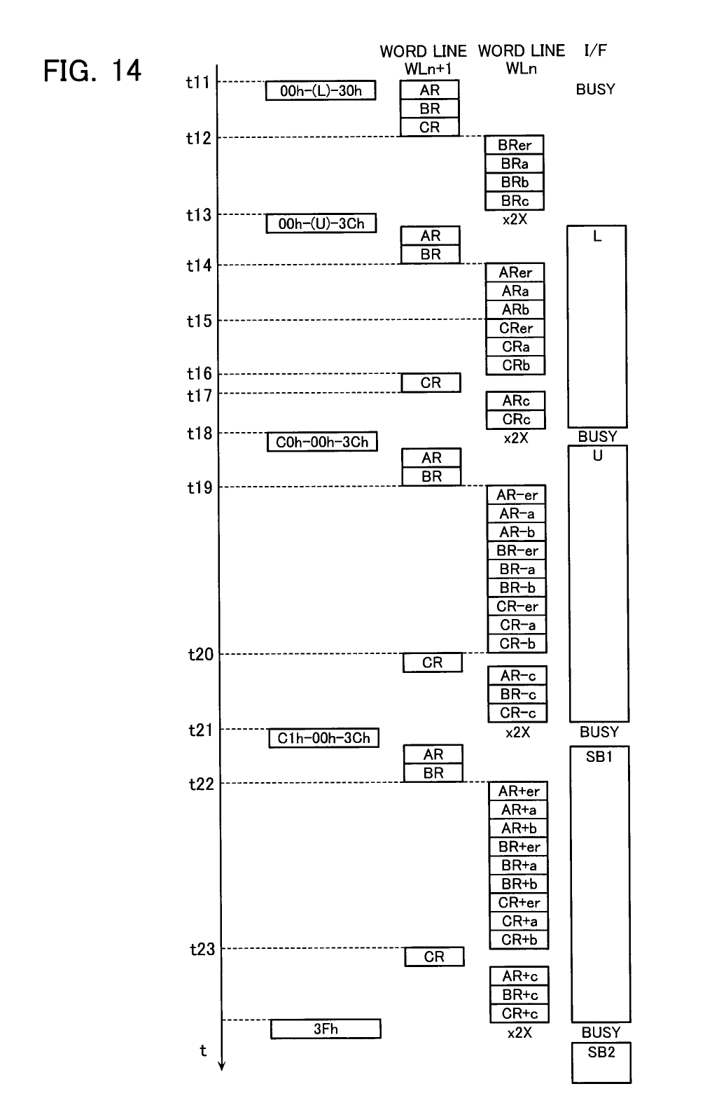

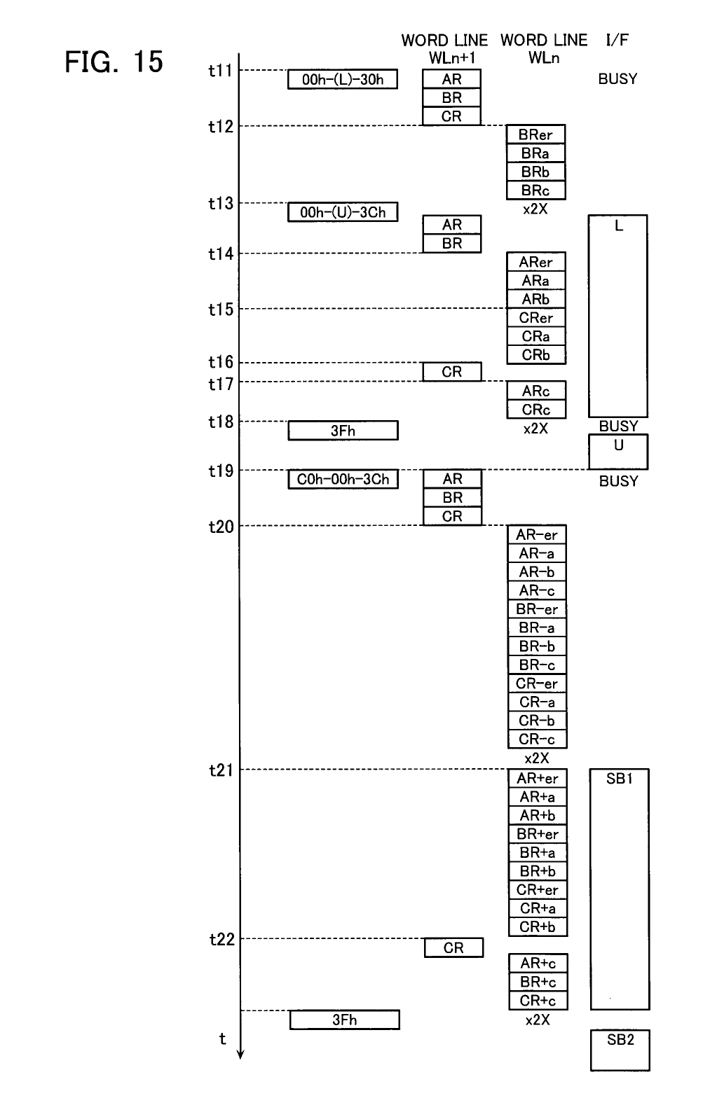

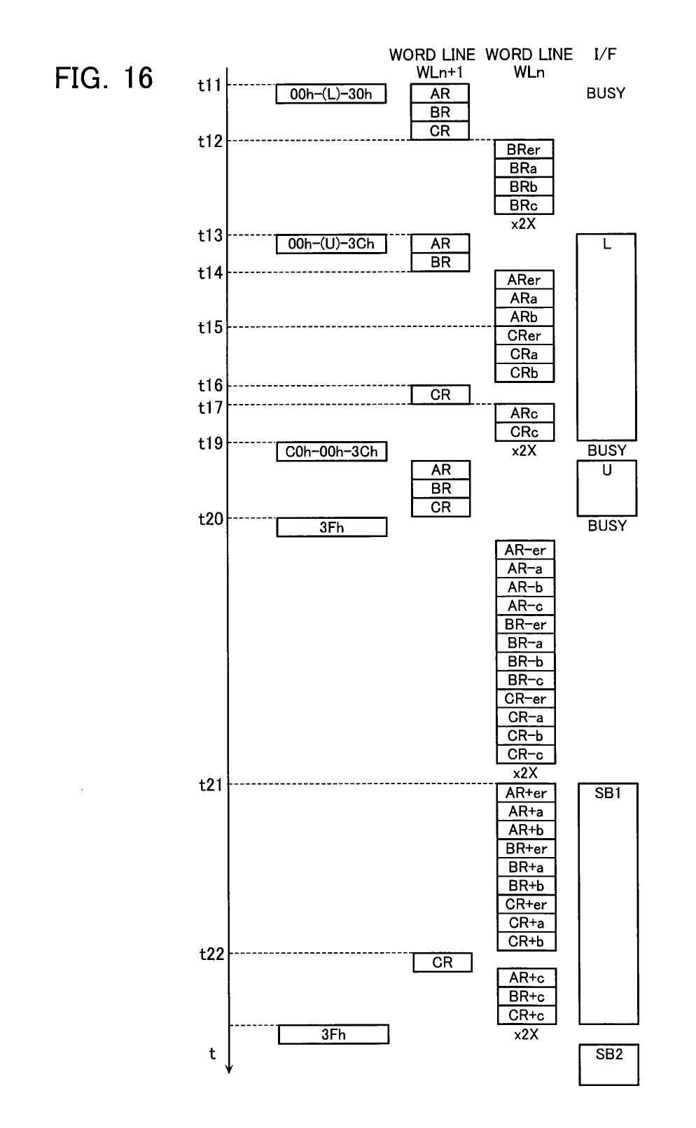

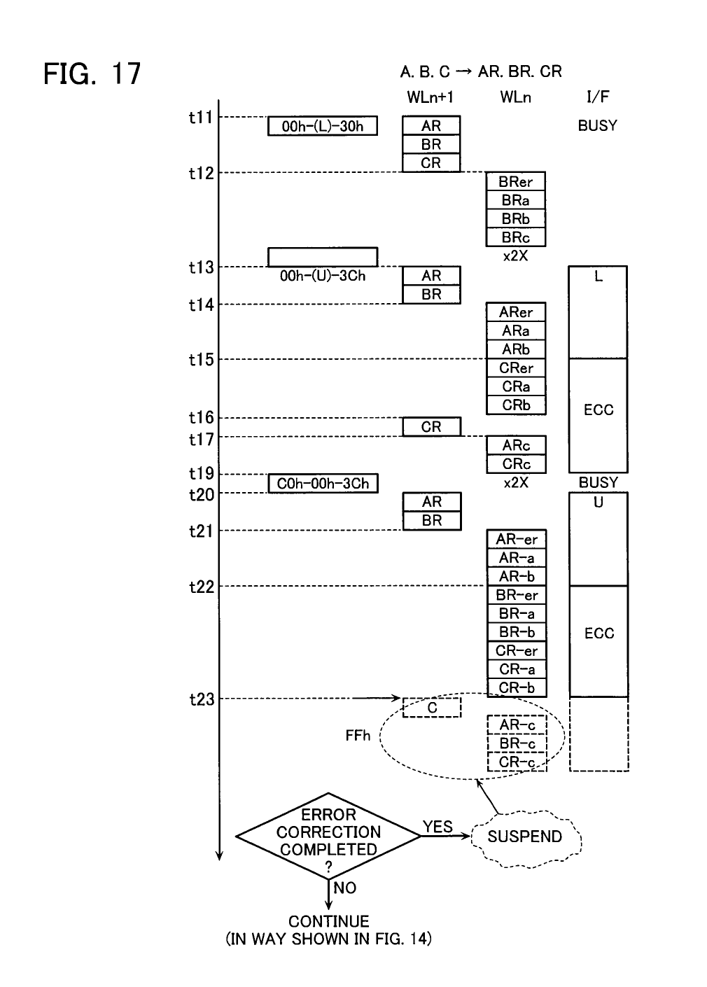

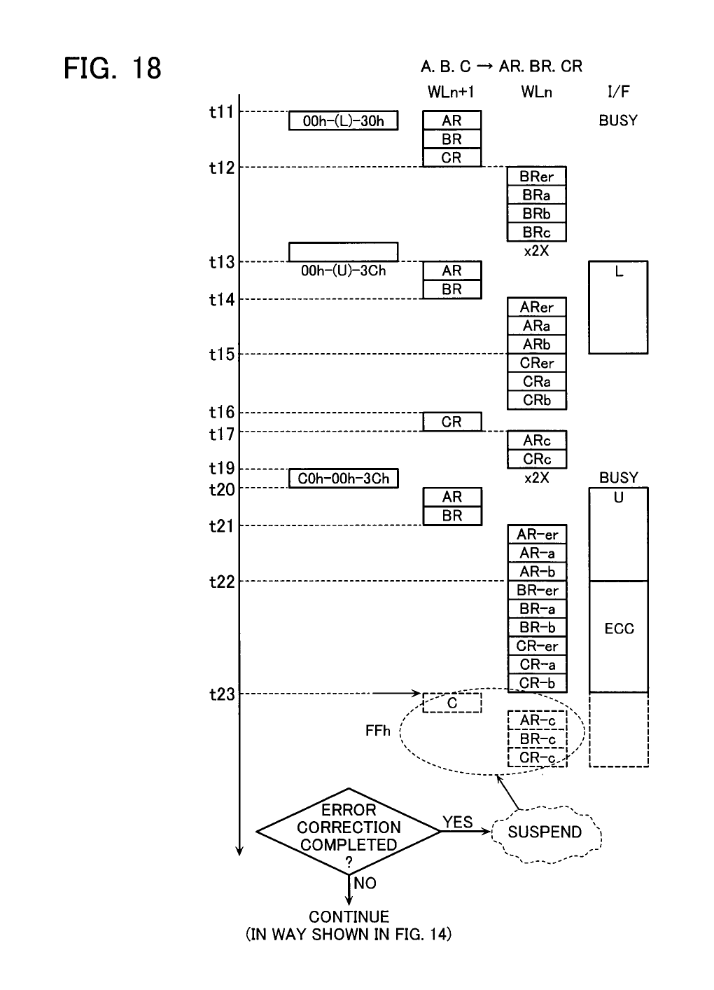

Next, a semiconductor memory device of the second embodiment of the present invention will be explained with reference to FIG. 14. The configuration of the semiconductor memory device of the second embodiment is generally the same as the first embodiment, and as shown in FIG. 1 to FIG. 6.

Further, the present embodiment is the same as the first embodiment in executing soft bit read in addition to hard bit read and in employing the corrective reading scheme. However, the present embodiment is different from the first embodiment in the procedure of reading from a selected memory cell MCn and from an adjoining memory cell MCn+1, specifically the procedure of applying the various voltages to the selected word line WLn and to the adjoining word line WLn+1. This different procedure will now be explained with reference to FIG. 14.

First, at timings t11 and t12, the same operations as in the first embodiment are executed.

After another read command is issued at the subsequent timing t13, data read out at the voltage BR, which is selected and retained in the data latch DLX at the timing t12, is externally output via the external interface I/F as the lower-order data (LOWER) of a memory cell MCn.

Meanwhile, concurrently with this, the adjoining word line WLn+1 is applied with only the voltages AR and BR, and data read out here is stored in the data latches DL0 and DL1. In other word, only part of the operation of reading 2-bit data from a memory cell MCn+1 is executed, and the remaining part will be executed from a timing t16, which is after a subsequent operation to the selected word line WLn is completed.

With the voltages AR and BR applied to the adjoining memory cell MCn+1, it is determined whether:
(1) the adjoining memory cell MCn+1 has the threshold voltage distribution ER (data “11”);
(2) the adjoining memory cell MCn+1 has the threshold voltage distribution A (data “01”); or
(3) the adjoining memory cell MCn+1 has either the threshold voltage distribution B or C (data “00” or “10”).

The result of this determination is stored in the data latches DL0 and DL1 as 2-bit data.

Subsequently, at a timing t14, the selected word line WLn is activated to read a selected memory cell MCn, but with only three levels of voltages ARer, ARa, and ARb applied to the selected word line WLn as the voltage AR. Application of the voltage ARc is not executed at this stage, but will be done at a timing t17, which is after a subsequent reading operation to the adjoining word line WLn+1 is completed.

Then, in a case where the adjoining memory cell MCn+1 falls under the above (1), read-out data obtained for the voltage ARer is selected and retained in the data latch DL0 or DL1 (here, data latch DL0). In a case where the adjoining memory cell MCn+1 falls under the above (2), read-out data obtained for the voltage ARa is selected and retained in the data latch DL0. In a case where the adjoining memory cell MCn+1 falls under the above (3), read-out data obtained for the voltage ARb is selected and retained in the data latch DL0.

From a timing t15, the data retained in the data latch DL0 is externally output via the external interface I/F. Concurrently with this, the selected word line WLn is applied with only three levels of voltages CRer, CRa, and CRb as the voltage CR (application of the voltage CRc is not executed at this stage). Then, as in the case of the voltage AR, in accordance with which of the above (1) to (3) the data read out from the adjoining memory cell MCn+1 falls under, any one of the three sets of read-out data obtained at the voltages CRer, CRa, and CRb is selected and retained in the data latch DL1. That is, at the timings t14 and t15, only part of the hard bit read operation to the memory cell MCn is executed, and the remaining part will be executed at a timing t17, which is after the remaining part of the reading operation to the memory cell MCn+1, which is to be explained next, is completed.

At the subsequent timing t16, the data that has been obtained by applying the voltage CR is externally output from the data latch DL1 via the external interface. Concurrently with this, the voltage CR is applied to the adjoining word line WLn+1. By the application of this voltage CR, it is determined whether the data retained in the adjoining memory cell MCn+1 has been associated with the threshold voltage distribution C (data “10”), or with any of the other distributions ER, A, and B (data “11”, “01”, and “00”). The result of this determination is stored in the data latch DL1.

At the subsequent timing t17, the voltages ARc and CRc, which were not applied at the timings t14 and t15, are sequentially applied to the selected word line WLn, and data based on this application are read out. In accordance with the data stored in the data latch DL1, determination is made on the data read out here whether they should replace the already read-out data obtained for the voltages AR and CR, or the already read-out data obtained for the voltages AR and CR should be kept.

With this, the hard bit read operation to the memory cell MCn is completed. Unlike in the first embodiment, in the present embodiment, the operation of applying the plural kinds of voltages (AR, BR, and CR) to the adjoining word line WLn+1 and the operation of applying the plural kinds of voltages (ARer, ARa, ARb, ARc, CRer, CRa, CRb, and CRc) to the selected word line WLn are respectively divided into a plurality of steps from the timing t13 to the timing t17 (each operation is executed as divided into predetermined smaller units, such that a part of one operation interrupts a part of the other operation). This enables to reduce the storage capacity of the data latches, leading to a faster reading operation than done in the first embodiment.

Next, at a timing t18, while outputting of the upper-order data (UPPER) of the selected memory cell MCn, which is the result of the reading operation at the timing t17, is executed via the external interface I/F concurrently, the voltages AR and BR are applied to an adjoining memory cell MCn+1 in accordance with a new read command, and like as described above, it is determined whether:
(1) the adjoining memory cell MCn+1 has the threshold voltage distribution ER (data “11”);
(2) the adjoining memory cell MCn+1 has the threshold voltage distribution A (data “01”); or
(3) the adjoining memory cell MCn+1 has either the threshold voltage distribution B or C (data “00” or data “10”).

The result of the determination is stored in the data latches DL0 and DL1 as 2-bit data.

At the subsequent timing t19, for executing a part of a first soft bit read operation, the voltages AR−, BR−, and CR− are applied to the selected word line WLn with each switched among three levels of voltages (AR−er, AR−a, and AR−b; BR−er, BR−a, and BR−b; CR−er, CR−a, and CRb). Likewise, among the four levels of the respective voltages AR−, BR−, and CR−, AR−c, BR−c, and CR−c are not applied at this stage. These voltages will be applied via (after) an operation described later of applying a voltage to the adjoining word line WLn+1.

One of three sets of data obtained at the voltages AR−er, AR−a, and AR−b is selected in accordance with the data stored in the data latches DL0 and DL1, stored in the data latch DLX, and then externally output via the external interface I/F. The same operation is executed for the data obtained at the voltages BR−er, BR−a, and BR−b. The same is executed for the data obtained at the voltages CR−er, CR−a, and CR−b likewise.

After this, at a timing t20, the voltage CR is applied to the adjoining word line WLn+1, and the data read out at this voltage CR is stored in the data latch DL1. After this, the voltages AR−c, BR−c, and CR−c, which were not applied at the timing t19, are sequentially applied to the selected word line WLn, and data based on these voltages are read out. In accordance with the data stored in the data latch DL1, determination is made on the data read out here whether they should replace the already ready-out data obtained for the voltages AR−, BR−, and CR−, or the already read-out data obtained for the voltage AR−, BR−, and CR− should be kept.

Subsequently, at timings t21, t22, and t23, the same operation as done for the voltages AR−, BR−, and CR− is executed for the voltages AR+, BR+, and CR+ (second soft bit read operation). The operation at the timings t21 to t23 enables soft bit read to be executed while the selected memory cell MCn is in the optimum state corresponding to the state of the adjoining memory cell MCn+1.

Also in this soft bit read operation (from the timing t19), an operation sequence for the adjoining word line WLn+1 and an operation sequence for the selected word line WLn are executed with each divided into predetermined smaller units, such that these sequences are executed alternately with the divided procedures of one sequence interrupted by the other sequence. By alternately executing the operations for the selected word line WLn and the adjoining word line WLn+1, it is possible to reduce the storage capacity of the data latches and increase the speed of the reading operation.

### Third Embodiment

Next, a semiconductor memory device of the third embodiment of the present invention will be explained with reference to FIG. 15. The configuration of the semiconductor memory device of the third embodiment is generally the same as the first embodiment, and as shown in FIG. 1 to FIG. 6.

The third embodiment is the same as the first and second embodiments in executing soft bit read in addition to hard bit read and in employing the corrective reading scheme.

An operation sequence for the adjoining word line WLn+1 and an operation sequence for the selected word line WLn will be executed with each divided and with the divided procedures interrupted by the other sequence, which is the same as the second embodiment. The operation of the third embodiment will be explained below with reference to FIG. 15, with a main focus put on differences from the operation of the second embodiment.

First, from timings t11 to t17, the same operations as in the second embodiment are executed.

Next, from a timing t18, the upper-order data (UPPER) of a memory cell MCn obtained by hard bit read is read out via the external interface I/F in accordance with a command. Then, from a timing t19, a soft bit read operation is started. At the timing t19, a reading operation to an adjoining memory cell MCn+1 along the adjoining word line WLn+1 is executed in accordance with a read command, so the voltages AR, BR, and CR are sequentially applied to the adjoining word line WLn+1. As a result, 2-bit data corresponding to four-value data stored in the adjoining memory cell MCn+1 is read out via the calculation circuit 31, and stored in the two data latches DL1 and DL0 in the data register 3b shown in FIG. 9.

Next, at timings t20 to t21, a first soft bit read operation based on the voltages AR−, BR−, and CR− is executed at the timing t20, and a second soft bit read operation based on the voltages AR+, BR+, and CR+ is then executed at the timing t21. In the second embodiment, the operation for the first soft bit read is executed as alternated with the reading operation to the adjoining word line WLn+1 and as divided into smaller units. As compared with this, in the present embodiment, the first soft bit read operation based on the voltages AR−, BR−, and CR− is executed simultaneously without being interrupted by a reading operation to the adjoining word line WLn+1 as shown in FIG. 15. That is, the voltages AR−c, BR−c, and CR−c are applied collectively (successively) with the other voltages, and a total of twelve kinds of voltages are applied sequentially. The result of this reading is stored in the data latch DLX.

Successively, at the timing t21, the read result of the first soft bit read is externally transferred from the data latch DLX via the external interface I/F, and concurrently with this, the second soft bit read operation is executed by applying the voltages AR+, BR+, and CR+ to the word line WLn. Like in the second embodiment, the second soft bit read follows a course of executing application of the voltages AR+c, BR+c, and CR+c separately from application of the other voltages, and during this execution the voltage CR is applied to the word line WLn+1. Following this course will produce an empty capacity in the data latches DL0 and D11. With the use of this empty capacity, outputting of the first soft bit read data obtained at the timing t20 can be executed concurrently.

### Fourth Embodiment

Next, a semiconductor memory device of the fourth embodiment of the present invention will be explained with reference to FIG. 16. The reading operation of the configuration of the semiconductor memory device of the fourth embodiment is generally the same as the third embodiment, but different from the third embodiment in that at a timing t19, reading of data from a memory cell MCn+1 along the adjoining word line WLn+1 (application of the voltages AR, BR, and CR) and outputting of the upper-order data (UPPER) of a memory cell MCn that has been read out previously and retained in the data latch are executed concurrently. The fourth embodiment is the same as the third embodiment in the other points.

### Fifth Embodiment

Next, a semiconductor memory device of the fifth embodiment of the present invention will be explained with reference to FIG. 17. The configuration of the semiconductor memory device of the fifth embodiment is generally the same as the first embodiment, and as shown in FIG. 1 to FIG. 6.

The fourth embodiment is the same as the first to third embodiments in executing soft bit read in addition to hard bit read and in employing the correcting reading scheme. An operation sequence for the adjoining word line WLn+1 and an operation sequence for the selected word line WLn will be executed with each divided and with the divided procedures interrupted by the other sequence, which is the same as the second and third embodiments.

However, in the present embodiment, parity data for error correction of lower-order page data (lower-order page parity data) and parity data for error correction of upper-order page data (upper-order page parity data) are read out from timings t12 to t13 and from timings t14 to t16 respectively. Then, error correction based on the lower-order page parity data and error correction based on the upper-order page parity data are executed from timings t15 to t19 and from timings t22 to t23 respectively, after reading of lower-order page data (L) and upper-order page data (U) (timings t13 to t15 and timings t19 to t22). However, these error corrections may be executed concurrently with reading of data from the word lines WLn+1 and WLn as shown in FIG. 17. That is, they may be executed between time t13 and t19, and between time t20 and t23.

In a case where it is determined as a result of the error correction based on the parity data that a soft read operation is unnecessary, the soft read operation from a timing t23 is called off . This enables to shorten the time required for data reading. In a case where it is determined as a result of the error correction based on the parity data that error correction is not satisfactory, the same operation as in FIG. 14 is executed.

Note that as shown in FIG. 18, parity data for the data of a whole word line including the upper page data and lower page data may be generated, and error correction based on this parity data may be executed from timings t22 to t23.

### [Others]

Though embodiments of the invention having been explained, the present invention is not limited to these embodiments but various modifications, addition, etc. may be made thereonto within the scope of the spirit of the invention.

What is claimed is:

1. A semiconductor memory device, comprising:
a memory cell array including a plurality of memory cells arranged therein, the memory cells being capable of storing plural-bit information associated with a plurality of threshold voltage distributions;
a sense amplifier circuit configured to read out data retained in the memory cells, and threshold voltage information indicating where in one of the plurality of threshold voltage distributions a threshold voltage of the memory cell is located;
a first data retaining circuit configured to retain the data and the threshold voltage information that are read out from the memory cell;
a second data retaining circuit configured to retain the data and the threshold voltage information read out from the memory cell, and externally output them;
a calculation device configured to perform a calculation among the data retained by the first data retaining circuit, the data retained by the second data retaining circuit, and data read out by the sense amplifier circuit; and
a control circuit configured to control a reading operation, a writing operation, and an erasing operation toward the memory cell array,
the control circuit being configured to execute:
a first operation of reading out data from an adjoining memory cell connected to a second word line adjacent to a first word line connected to a selected memory cell as a target of data reading, and retaining the read-out data in the first data retaining circuit;
a second operation of further changing each of plural kinds of word line voltages among a plurality of values respectively, the word line voltages being applied to the first word line for reading out the data or the threshold voltage information, and selecting one of plural sets of data read out by the plurality of values of each of the word line voltages in accordance with the data retained in the first data retaining circuit; and
a third operation of externally outputting the data selected in the second operation, and
the third operation being executed simultaneously with one of the first operation and the second operation to be executed successively.

2. The semiconductor memory device according to claim 1, wherein in the second operation, the higher the threshold voltage for the data retained in the first data retaining circuit is, data that is read out by the larger value of the plurality of values of one of the plural kinds of word line voltages is selected.

3. The semiconductor memory device according to claim 1, wherein the first operation and the second operation are divided into certain units, and a unit of the first operation and a unit of the second operation are executed alternately.

4. The semiconductor memory device according to claim 1, wherein the second operation includes an operation of transferring the selected data to the second data retaining circuit to retain it therein.

5. The semiconductor memory device according to claim 3, wherein in the second operation, the higher the threshold voltage for the data retained in the first data retaining circuit is, data that is read out by the larger value of the plurality of values of one of the plural kinds of word line voltages is selected.

6. The semiconductor memory device according to claim 3, wherein in the second operation, a part of the plurality of values of each of the plural kinds of word line voltages applied to the first word line is assigned to a first unit of the units, and a remaining part of the plurality of values is assigned to a second unit different from the first unit.

7. The semiconductor memory device according to claim 6, wherein in the second operation, the higher the threshold voltage for the data retained in the first data retaining circuit is, data that is read out by the larger value of the plurality of values of one of the plural kinds of word line voltages is selected.

8. The semiconductor memory device according to claim 6, wherein in the first operation, a voltage, out of plural kinds of word line voltages applied to the second word line, that is necessary for specifying higher-order bit information of the plural-bit information stored in the memory cell is assigned to a first unit of the units, and a remaining voltage is assigned to a second unit different from the first unit.

9. The semiconductor memory device according to claim 8, wherein in the second operation, the higher the threshold voltage for the data retained in the first data retaining circuit is, data that is read out by the larger value of the plurality of values of one of the plural kinds of word line voltages is selected.

10. The semiconductor memory device according to claim 1, wherein
the second operation includes reading of parity data, and
the third operation includes error check executed based on the parity data read out in the second operation.

11. A method of reading a semiconductor memory device, the semiconductor memory device including: a memory cell array including a plurality of memory cells arranged therein, the memory cells being capable of storing plural-bit information associated with a plurality of threshold voltage distributions; and a sense amplifier circuit configured to read out data retained in the memory cell and threshold voltage information indicating where in one of the plurality of threshold voltage distributions a threshold voltage of the memory cell is located, the method comprising:
a first operation of reading out data from an adjoining memory cell connected to a second word line adjacent to a first word line connected to a selected memory cell as a target of data reading, and retaining the read-out data as first data;
a second operation of further changing each of plural kinds of word line voltages among a plurality of values, the word line voltages being applied to the first word line for reading out the data or the threshold voltage information, and selecting, as second data, one of plural sets of data that are read out by the plurality of values of each of the word line voltages in accordance with the first data; and
a third operation of executing external outputting of the second data simultaneously with one of reading of the first data and reading of the second data to be executed successively.

12. The method of reading the semiconductor memory device according to claim 11, wherein in the second operation, the higher the threshold voltage for the first data is, data that is read out by the larger value of the plurality of values of one of the plural kinds of word line voltages is selected.

13. The method of reading the semiconductor memory device according to claim 11, wherein the first operation and the second operation are divided into certain units, and a unit of the first operation and a unit of the second operation are executed alternately.

14. The method of reading the semiconductor memory device according to claim 13, wherein in the second operation, the higher the threshold voltage for the first data is, data that is read out by the larger value of the plurality of values of one of the plural kinds of word line voltages is selected.

15. The method of reading the semiconductor memory device according to claim 13, wherein in the second operation, a part of the plurality of values of each of the plural kinds of word line voltages applied to the first word line is assigned to a first unit of the units, and a remaining part of the plurality of values is assigned to a second unit different from the first unit.

16. The method of reading the semiconductor memory device according to claim 15, wherein in the second operation, the higher the threshold voltage for the first data is, data that is read out by the larger value of the plurality of values of one of the plural kinds of word line voltages is selected.

17. The method of reading the semiconductor memory device according to claim 15, wherein in the first operation, a voltage, out of plural kinds of word line voltages applied to the second word line, that is necessary for specifying higher-order bit information of the plural-bit information stored in the memory cell is assigned to a first unit of the units, and a remaining voltage is assigned to a second unit different from the first unit.

18. The method of reading the semiconductor memory device according to claim 17, wherein in the second operation, the higher the threshold voltage for the first data is, data that is read out by the larger value of the plurality of values of one of the plural kinds of word line voltages is selected.

19. The method of reading the semiconductor memory device according to claim 11, wherein
the second operation includes reading of parity data, and
the third operation includes error check executed based on the parity data read out in the second operation.
